(19) United States
(12) Patent Application Publication
(10) Pub. No.: US 2007/0007244 A1
(43) Pub. Date: Jan. 11, 2007

(54) DETECTION OF LOSS OF PLASMA CONFINEMENT

(75) Inventors: Habib Hichri, Poughkeepsie, NY (US); Kaushik A. Kumar, Beacon, NY (US); Helen L. Maynard, Hopewell Junction, NY (US)

Correspondence Address: SCHMEISER, OLSEN & WATTS, 22 CENTURY HILL DRIVE, SUITE 302, LATHAM, NY, 12110, US

(73) Assignee: INTERNATIONAL BUSINESS MACHINES CORPORATION, Armonk, NY (US)

(21) Appl. No.: 11/160,671

(22) Filed: Jul. 5, 2005

(51) Int. Cl. G01L 21/30; H01L 21/306; C23F 1/00; B44C 1/22

(52) U.S. Cl. 216/67; 156/345.24; 216/59

(57) ABSTRACT

A system and method for detecting a loss of plasma confinement. The system includes a plasma chamber that includes a plasma space and a non-plasma space. A plasma apparatus generates a plasma within the plasma space. The non-plasma space surrounds the plasma space and is separated from the plasma space by a confinement barrier that is adapted to confine the plasma in the plasma space during performance of an operational process by the plasma on a substrate disposed within the plasma space. Plasma detectors distributed on bounding surfaces of the non-plasma space are adapted to detect plasma that has escaped from the plasma space during performance of the operational process. The operational process is performed while the plasma detectors are monitoring the non-plasma space for a presence of the escaped plasma in the non-plasma space. If the monitoring has detected the escaped plasma, then the operational process is aborted.

### TECHNICAL FIELD

The present invention relates to a system and method of for detecting a loss of plasma confinement.

### RELATED ART

A plasma processing system may confine a plasma to the center of a plasma chamber to prevent interaction with walls of the plasma chamber. Unfortunately, the plasma escape its confinement, causing a drastic change in processing conditions in the plasma chamber. Thus, there is a need for a system and method for mitigating adverse effects of loss of plasma confinement.

### SUMMARY OF THE INVENTION

The present invention provides a system for detecting a loss of plasma confinement, comprising:

a plasma chamber enclosed by a first wall, a second wall opposite the first wall, and a sidewall disposed between the first wall and the second wall, said first and second walls having respective first and second surfaces which bound an interior space of the plasma chamber, said interior space of the plasma chamber comprising a plasma space and a non-plasma space, said non-plasma space surrounding and being exterior to the plasma space, said plasma chamber having a plasma apparatus therein for generating a plasma within the plasma space;

a confinement barrier within the plasma chamber and bounding the plasma space, said confinement barrier having a barrier surface exterior to the plasma space and facing the non-plasma space, said confinement barrier adapted to confine the plasma within the plasma space during a performance of an operational process by the plasma on a substrate that is disposed within the plasma space; and

N plasma detectors, said N at least 1, each detector of the N detectors independently mounted on a mounting surface selected from the group consisting of the first surface, the second surface, and the barrier surface, each plasma detector adapted to detect in the non-plasma space escaped plasma that has escaped from the plasma space during the performance of the operational process.

The present invention provides a method for detecting a loss of plasma confinement, comprising:

providing a system, said system comprising:

a plasma chamber enclosed by a first wall, a second wall opposite the first wall, and a sidewall disposed between the first wall and the second wall, said first and second walls having respective first and second surfaces which bound an interior space of the plasma chamber, said interior space of the plasma chamber comprising a plasma space and a non-plasma space, said non-plasma space surrounding and being exterior to the plasma space, said plasma chamber having a plasma apparatus therein for generating a plasma within the plasma space;

a confinement barrier within the plasma chamber and bounding the plasma space, said confinement barrier having a barrier surface exterior to the plasma space and facing the non-plasma space, said confinement barrier adapted to confine the plasma within the plasma space during a performance of an operational process by the plasma on a substrate that is disposed within the plasma space; and

N plasma detectors, said N at least 1, each detector of the N detectors independently mounted on a mounting surface selected from the group consisting of the first surface, the second surface, and the barrier surface, each plasma detector adapted to detect in the non-plasma space escaped plasma that has escaped from the plasma space during the performance of the operational process;

initiating the operational process by the plasma on the substrate; performing the operational process while monitoring the non-plasma space for a presence of said escaped plasma in the non-plasma space, said monitoring being conducted by the at least one plasma detector; and

if said monitoring has detected said escaped plasma, then aborting the operational process, else continuing said performing the operational process until either the operational process has been completed or said monitoring has detected said escaped plasma.

The present invention provides a system and method for mitigating adverse effects of loss of plasma confinement.

### BRIEF DESCRIPTION OF THE DRAWINGS

FIG. 1 depicts a simplified a cross-sectional view of a plasma chamber in which a plasma is confined to a plasma space of the plasma chamber, in accordance with the present invention.

FIG. 2 depicts the plasma chamber of FIG. 1 wherein confinement of the plasma to the plasma space has been lost, resulting in plasma being is in a non-plasma space of the plasma chamber, in accordance with the present invention.

FIG. 3 depicts the plasma chamber of FIG. 2 wherein plasma detectors have been distributed in the non-plasma space to detect a presence of plasma in the non-plasma space, in accordance with embodiments of the present invention.

FIG. 4 depicts a plasma chamber having a plasma apparatus therein for generating a plasma within a plasma space of the plasma chamber in which the plasma is confined, wherein plasma detectors are distributed in a non-plasma space of the plasma chamber to detect a presence of plasma in the non-plasma space, in accordance with embodiments of the present invention.

FIG. 5 depicts the plasma chamber of FIG. 4, wherein a solid angular range of detection sensitivity is shown for the plasma detectors in the non-plasma space of the plasma chamber, in accordance with embodiments of the present invention.

FIGS. 6-9 depict a top view of the plasma chamber of FIGS. 4-5 for various distributions of detectors in the non-plasma space, in accordance with embodiments of the present invention.

FIG. 10 is a flow chart depicting a method for detecting a loss of plasma confinement during operation of a plasma apparatus within a plasma chamber, in accordance with embodiments of the present invention.

### DETAILED DESCRIPTION OF THE INVENTION

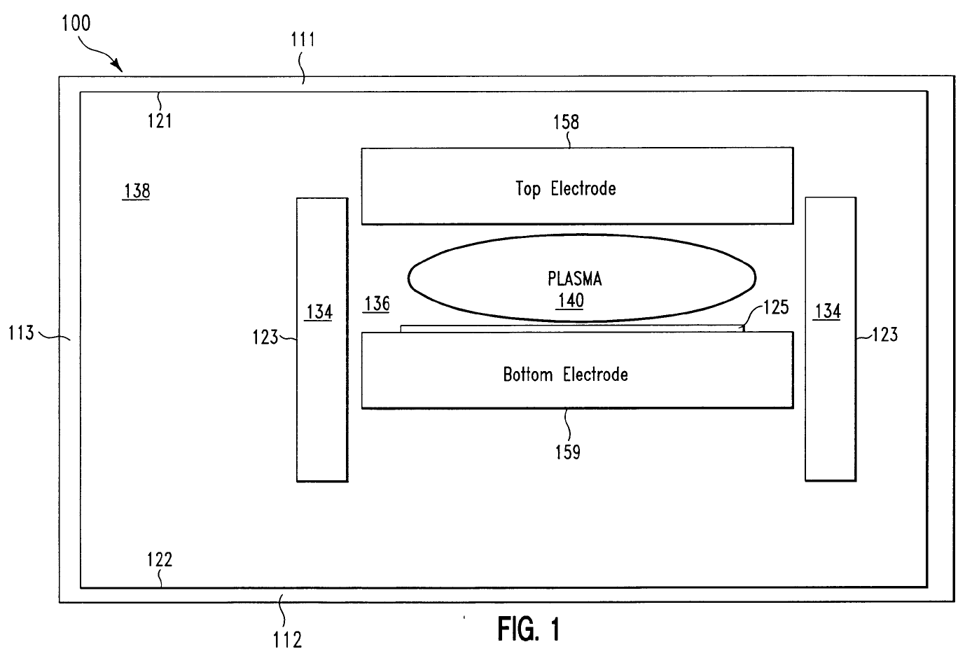

FIG. 1 depicts a simplified plan view of a plasma chamber 100 in which a plasma 140 is confined to a plasma space 136 of the plasma chamber 100, in accordance with the present invention. The plasma chamber 10 comprises a top wall 111, a bottom wall 112 opposite the top wall 111, and a side wall 113 disposed between the top wall 111 and the bottom wall 112. The top wall 111 and the bottom wall 112 have respective interior surfaces 121 and 122 which bound the interior space of the plasma chamber 110. The interior space of the plasma chamber 100 comprises a plasma space 136 and a non-plasma space 138. The non-plasma space 138 surrounds and is exterior to the plasma space 136. The plasma chamber 100 has a plasma apparatus therein for generating the plasma 140 within the plasma space 136. The plasma apparatus comprises a top electrode 158 and a bottom electrode 159.

A confinement barrier 134 within the plasma chamber 100 bounds the plasma space 136. The confinement barrier 134 comprises a barrier surface 123 exterior to the plasma space 136 and facing the non-plasma space 138. The confinement barrier 134 is adapted to confine the plasma 140 within the plasma space 136 during an operational process (e.g., etching) that is being performed by the plasma 40 on a substrate (e.g., a semiconductor wafer 125) that is disposed within the plasma space 136.

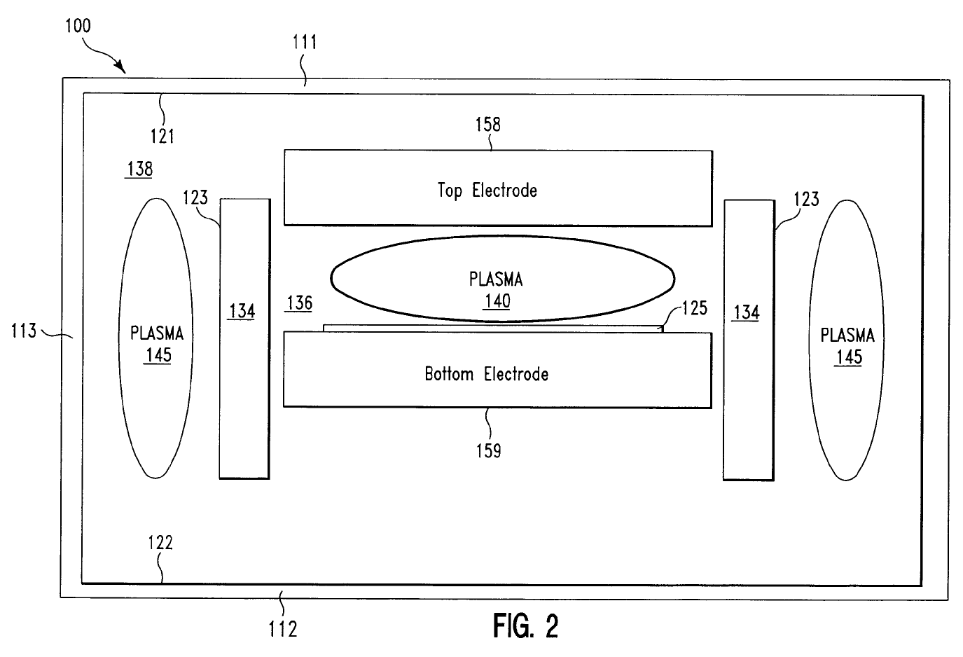

FIG. 2 depicts the plasma chamber 10 of FIG. 1 wherein confinement of the plasma 140 to the plasma space 136 has been lost, resulting in plasma 145 being is in the non-plasma space 138, in accordance with the present invention. The plasma 145 had previously been comprised by the plasma 140 while being confined to the plasma space 136, but subsequently escaped through or past the confinement barrier 134 to become disposed in the non-plasma space 138 as shown in FIG. 2.

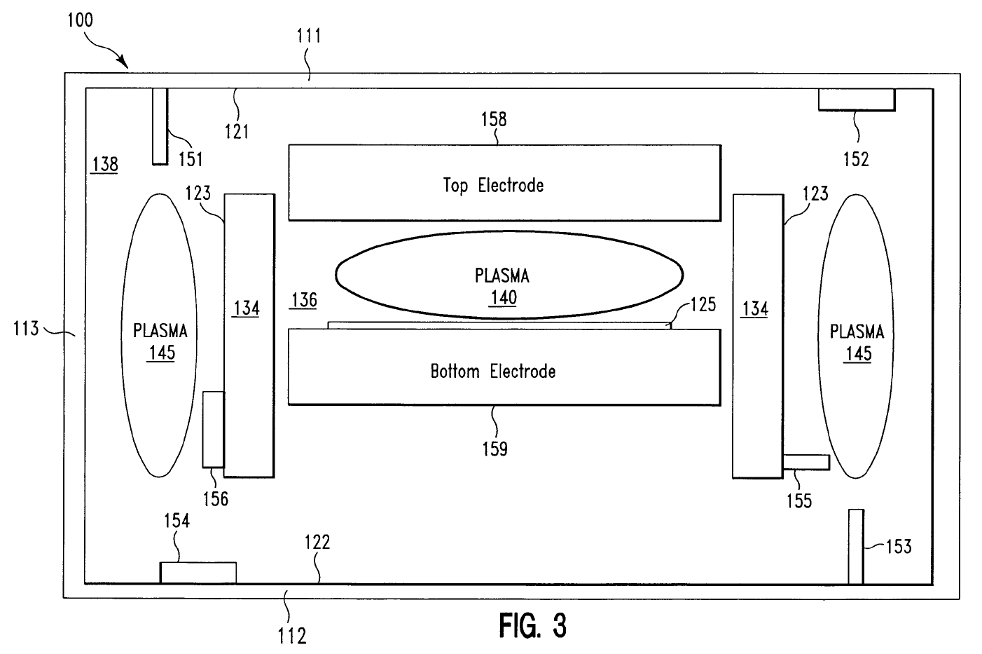

FIG. 3 depicts the plasma chamber 100 of FIG. 2 wherein plasma detectors 151-156 have been distributed in the non-plasma space 138 to detect a presence of plasma 145 in the non-plasma space 138, in accordance with embodiments of the present invention. Plasma detectors 151-152 are on the surface 121 of the top wall 111 of the plasma chamber 100, plasma detectors 153-154 are on the surface 122 of the bottom wall 112 of the plasma chamber 100, and plasma detectors 155-156 are on the barrier surface 123 of the confinement barrier 134. Plasma detectors 151, 153, and 155 are Langmuir probes which are sensitive to electrical characteristics of a plasma and can therefore detect the presence of the plasma in the vicinity of the Langmuir probe. Plasma detectors 152, 154, and 156 are photodetectors (e.g., photdiodes) which are adapted to detect the presence of photons in the vicinity of the photodetector, said photons being emitted by the plasma in the non-plasma space 138. In addition to Langmuir probes and phtodetectors, any type of plasma detector known to a person of ordinary skill in the art may be mounted to any of surfaces 121-123 to detect the presence of the plasma 145 in the non-plasma space 138. The scope of the present invention generally includes all types of plasma detectors and in any combination as to detector type and number of detectors. For example, the plasma detectors may all be of one type (e,g., all plasma detectors are Langmuir probes, all plasma detectors are photodetectors, etc.). As another example, the plasma detectors may be a combination of different types (e.g., at least one Langmuir probe and at least one photodetector in a combination).

Adding plasma detectors (e.g., detectors 151-156) system to any, some, or all of the surfaces 121-123 facilitates an early detection of the loss of plasma confinement in the plasma space 136. In response to said early detection of the loss of plasma confinement, the plasma apparatus may be deactivated (i.e., powered down), thereby preventing additional substrates (e.g, wafers) from being incorrectly processed.

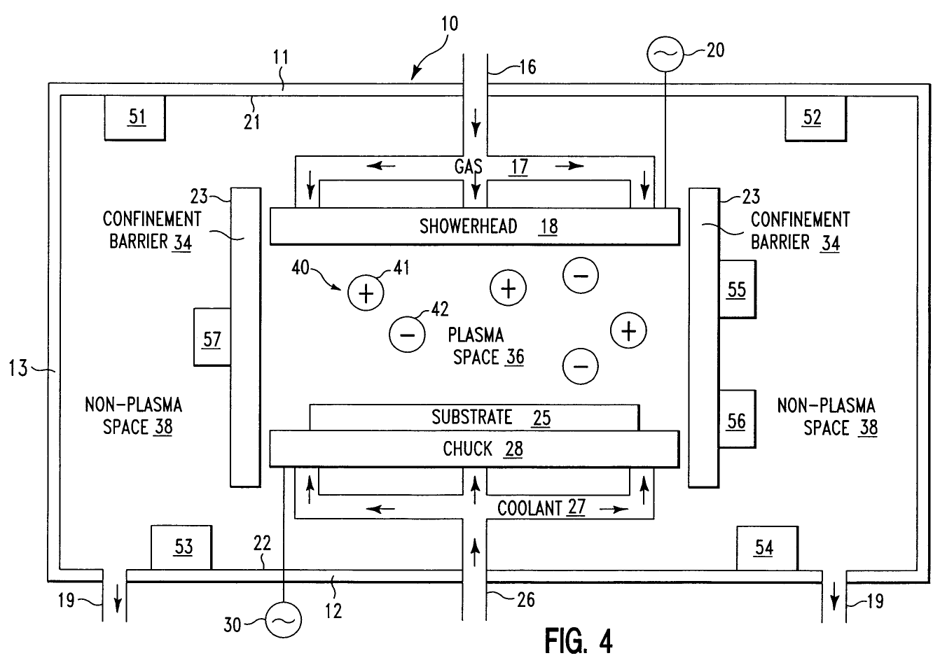

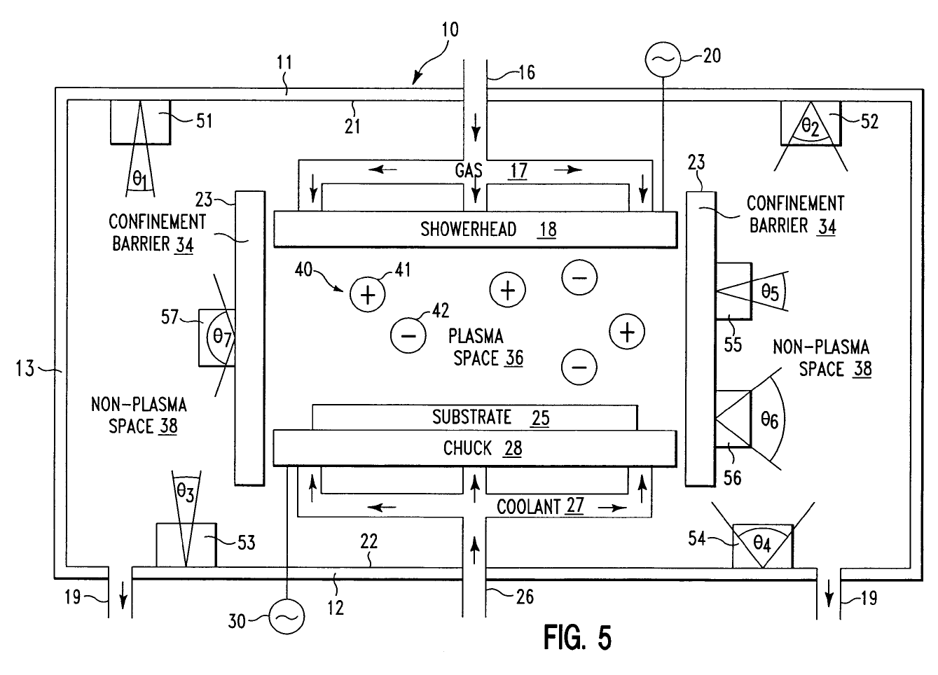

FIG. 4 depicts a cross-sectional view of a plasma chamber 10 having a plasma apparatus therein for generating a plasma 40 within a plasma space 36 of the plasma chamber 10 in which the plasma 40 is confined, in accordance with embodiments of the present invention. The plasma chamber 10 comprises a top wall 11, a bottom wall 12 opposite the top wall 11, and a side wall 13 disposed between the top wall 111 and the bottom wall 12. The top wall 111 and the bottom wall 12 have respective interior surfaces 21 and 22 which bound the interior space of the plasma chamber 10. The interior space of the plasma chamber 10 comprises a plasma space 36 and a non-plasma space 38. The non-plasma space 38 surrounds and is exterior to the plasma space 36. The plasma chamber 10 has a plasma apparatus therein for generating the plasma 40 within the plasma space 36.

The plasma apparatus comprises a showerhead 18 and a chuck 28. The showerhead 18 functions as a first electrode that is electrically coupled to a power supply 20, and the chuck 28 functions as a second electrode that is electrically coupled to a power supply 30. The power sources 20 and 30 may be a same power source such as a radio frequency (RF) power source. Alternatively, the power sources 20 and 30 may be different power source such as different RF power sources having different frequencies, or as different RF power sources having the same frequency and being phase-shifted with respect to each other.

After a gas 13 enters the plasma chamber 10 via gas inlet 16 and is distributed within the showerhead 18, the gas 13 enters the plasma space 36 and is ionized to form the plasma 40 in the plasma space 36. The power sources 20 and 30 supply power sufficient to ionize the gas 13 to generate the plasma 40. The plasma 40 comprises positively charged particles 41 (e.g., ions) and negatively charged particles 42 (e.g., electrons). The pump port 19 is used as outlet through which the plasma reaction byproducts are pumped out of the plasma chamber 10, which maintains the pressure in the plasma chamber.

A substrate 25 (e.g., a semiconductor wafer), disposed on the chuck 28, is operationally processed (e.g., etched) by the plasma 40. A coolant 27 enters the plasma chamber 10 via coolant inlet 26 and cools the chuck 28 and substrate 25 to maintain the substrate 25 at an approximately constant temperature that is substantially spatially uniform over the volume of the substrate 25.

A confinement barrier 34 within the plasma chamber 10 bounds the plasma space 36. The confinement barrier 34 comprises a barrier surface 23 exterior to the plasma space 36 and facing the non-plasma space 38. The confinement barrier 34 confines the plasma 40 to within the plasma space 36 during the operational process (e.g., an etching process) that is being performed by the plasma 40 on the substrate 25.

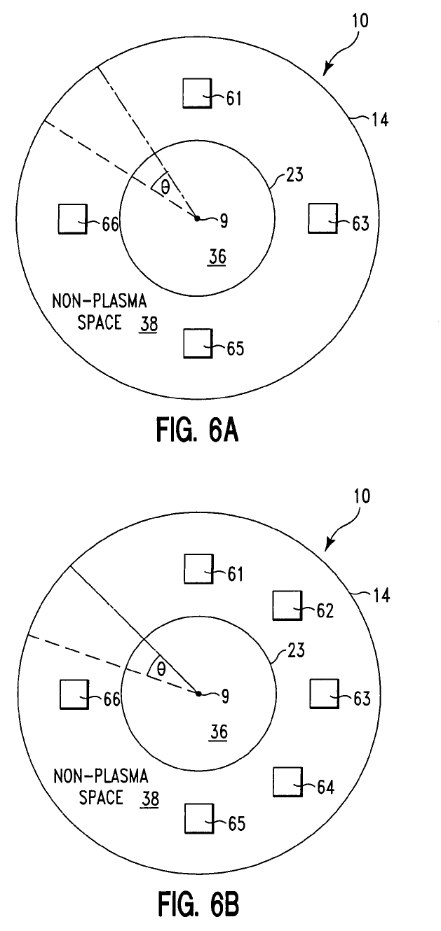

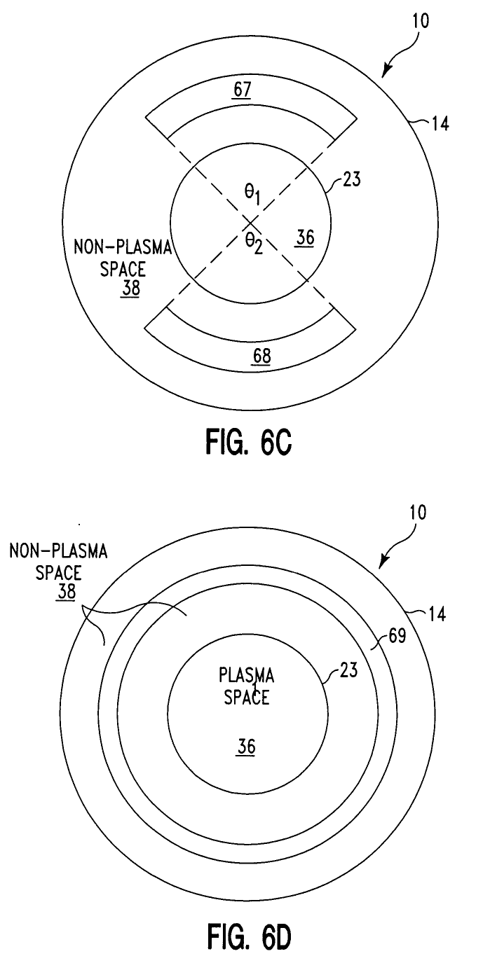

Plasma detectors 51-57 are distributed in the non-plasma space 38 to detect a presence of plasma in the non-plasma space 38 resulting from a loss of plasma confinement the plasma 40 to the plasma space 36 by the confinement barrier 34. Plasma detectors 51-52 are on the surface 21 of the top wall 11 of the plasma chamber 10, plasma detectors 53-54 are on the surface 22 of the bottom wall 12 of the plasma chamber 10, and plasma detectors 55-57 are on the barrier surface 23 of the confinement barrier 34. Plasma detectors 51-57 may each independently be any type of plasma detector known to a person of ordinary skill in the art. Examples of such plasma detectors include Langmuir probes and photodetectors. Any number of plasma detectors and any distribution of the plasma detectors on the surfaces 21-23 is within the scope of the present invention. Examples of plasma detector distributions on the surfaces 21-23 are described infra in conjunction with FIGS. 6-9.

FIG. 5 depicts the plasma chamber 10 of FIG. 4, wherein a solid angular range of detection sensitivity is shown for the plasma detectors 51-57, in accordance with embodiments of the present invention. Each detector 51-57 has a solid angular range of detection sensitivity that depends on the angular orientation of the detection component of the detector with respect to the surface that the detector is mounted on. The solid angular range of detection of a detector sensitivity may also be a function of the geometric shape of the detecting surface of the detector. With respect to the detectors 51-52 mounted on the surface 21 of the top wall 11, the solid angular range of detection (θ₂) of the detector 52 exceeds the solid angular range of detection (θ₁) of the detector 51 as shown. With respect to the detectors 53-54 mounted on the surface 22 of the bottom wall 22, the solid angular range of detection (θ₄) of the detector 54 exceeds the solid angular range of detection (θ₃) of the detector 53. With respect to the detectors 55-57 mounted on the barrier surface 23, the solid angular range of detection (θ₇) of the detector 57 exceeds the solid angular range of detection (θ₆) of the detector 56, and the solid angular range of detection (θ₆) of the detector 56 exceeds the solid angular range of detection (θ₅) of the detector 55. Although the angles θ₁-θ₇ are depicted as planar in the two-dimensional cross sectional view of FIG. 5, the angles θ₁-θ₇ are in actuality solid angles in the three-dimensional non-plasma space 38. Although a solid angle generally ranges in value from 0 to 4π steradians, the maximum solid angular range of detection of any of the detectors 51-57 is 2π steradians. As the solid angular range of detection increases, fewer detectors are needed to monitor the non-plasma space 38 to adequately detect a loss of plasma confinement event pertaining to loss of confinement of the plasma 40 within the plasma space 36.

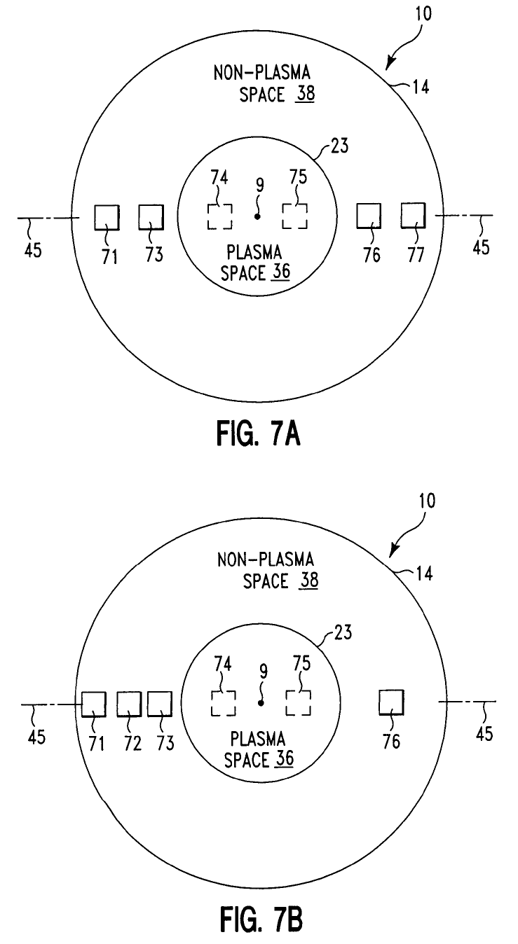

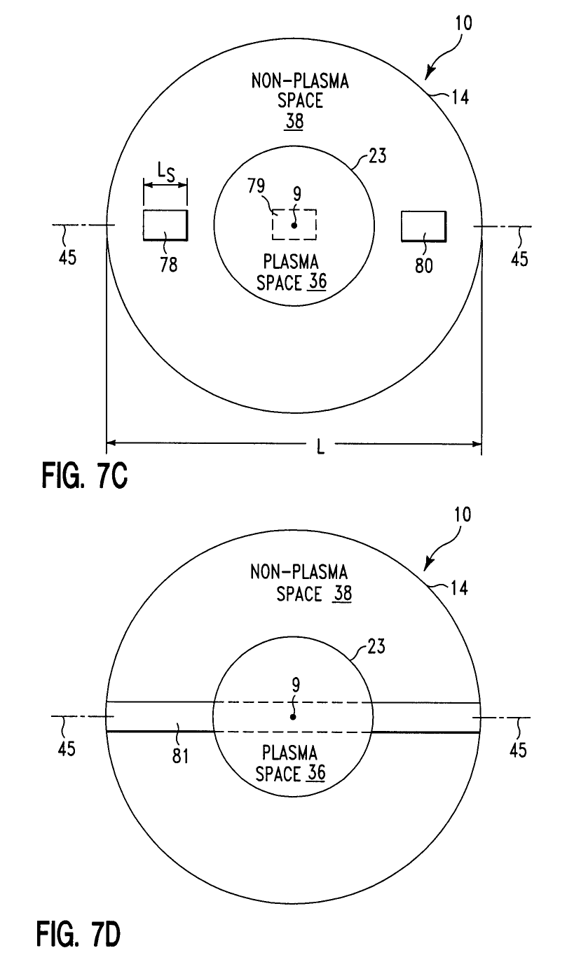

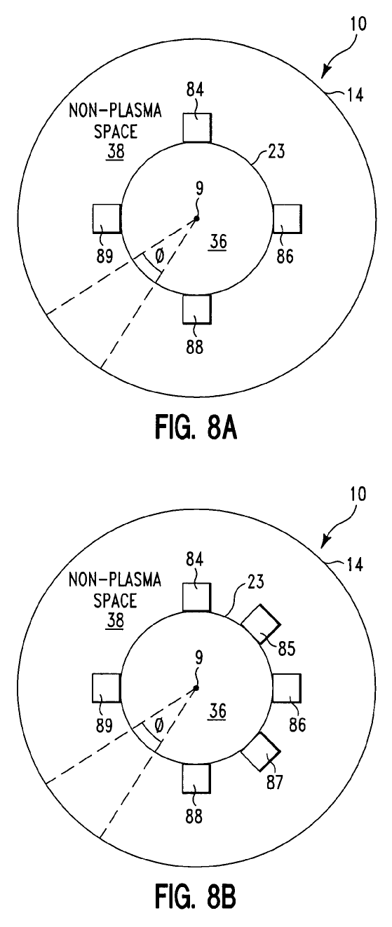

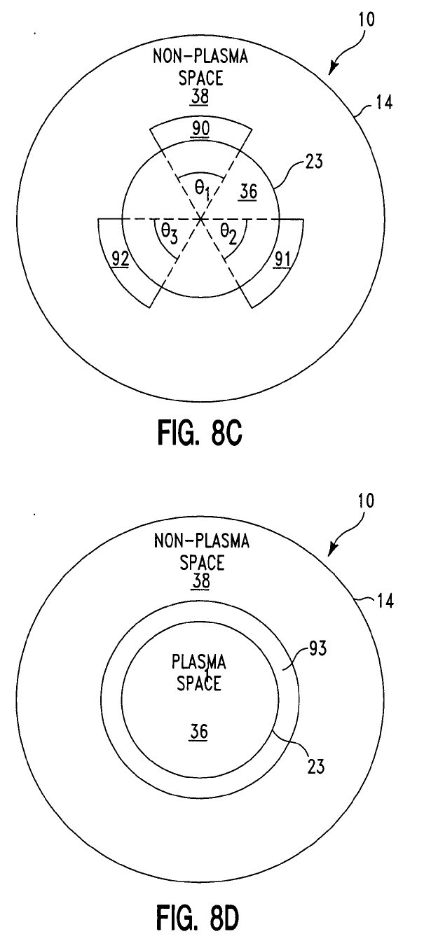

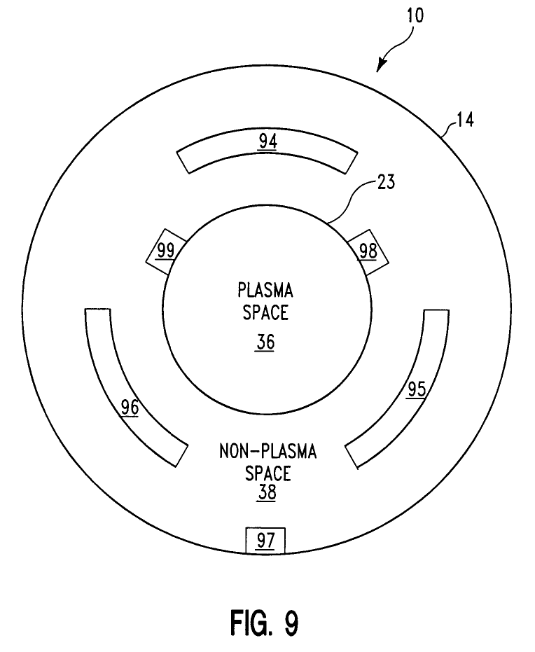

FIGS. 6A-6B (collectively, “FIG. 6”), FIGS. 7A-7B (collectively, “FIG. 7”), FIGS. 8A-8B (collectively, “FIG. 8”), and FIG. 9 depict a top view of the plasma chamber 10 of FIGS. 4-5 for various distributions of detectors in the non-plasma space 38, in accordance with embodiments of the present invention. FIGS. 6-9 each depict a surface 14, which represents either the surface 21 of the top wall 111 or the surface 22 of the bottom wall 12, of the plasma chamber 10 (see FIGS. 4-5). Each plasma detector in FIGS. 6-9 has a solid angular range of detection as discussed supra.

FIG. 6A depicts plasma detectors 61, 63, 65, and 66 mounted on the surface 14 (i.e., on the top wall 111 and/or the bottom wall 12 of FIGS. 4-5). The detectors 61, 63, 65, and 66 are about uniformly distributed azimuthally (i.e., with respect to azimuthal angle φ), wherein the azimuthal angle φ is measured with respect to a central point 9 in the plasma space 36.

FIG. 6B depicts FIG. 6A with additional plasma detectors 62 and 64 mounted on the surface 14, resulting in a non-uniform distribution of the detectors 61-66 with respect to an azimuthal angle φ. The higher density of detectors for the spatial distribution of detectors 61-65 with (respect to the angle φ) than the density of detectors for the spatial distribution of detectors 61, 66, and 65 (respect to the angle φ) may reflect such factors as, inter alia: a higher expectation of loss of plasma range of into the space where the detectors 61-65 are located than into the space where the detectors 61, 66, and 65 are located; a lower solid angular range of detection sensitivity for detectors 61-65 than for the detectors 61, 66, and 65, etc.

FIG. 6C depicts plasma detectors 67 and 68 mounted on the surface 14. The detector 67 extends continuously over an azimuthal angular extent φ₁. The detector 68 extends continuously over an azimuthal angular extent φ₂.

FIG. 6D depicts a plasma detector 69 mounted on the surface 14 and extending continuously in a ring formation. Accordingly, detector 69 is called a “ring detector”. Note if the angular extent φ₁ and/or φ₂ of the detectors 67-68 of FIG. 6C ware increased sufficiently to make detectors 67 and 68 continuous with respect to each other, then the ring detector 69 of FIG. 6D would result.

FIG. 7A depicts plasma detectors 71 and 73-77 mounted on the surface 14 (i.e., the surface 21 of the top wall 111 and/or the surface 22 of the bottom wall 12 of FIGS. 4-5). The detectors 71 and 73-77 are about uniformly distributed along a straight line 45 passing through the central point 9 in the plasma space 36. Detectors 74 and 75 are depicted with dashed lines to indicate that detectors 74 and 75 are located on the surface 14 and not in the plasma space 36.

FIG. 7B depicts FIG. 7A with detectors 71 and 73 spaced apart such that an additional plasma detector 72 is disposed between detectors 71 and 73, and with detector 77 removed. The density of detectors for the spatial distribution of detectors 71-73 in FIG. 7B (along the line 45) exceeds the density of detectors for the spatial distribution of detectors 71 and 73 in FIG. 7A (along the line 45). The density of detectors for the spatial distribution of detectors 76 and 77 in FIG. 7A (along the line 45) exceeds the density of detectors for the spatial distribution of detector 76 in FIG. 7B (along the line 45).

FIG. 7C depicts plasma detectors 78-80 mounted on the surface 14. The detector 79 is located on the surface 14 and not in the plasma space 36. The detectors 78-80 each extend continuously over a finite linear extent along the line 45. Detectors 78-80 are called “segment detectors”, since detectors 78-80 extend continuously over finite a segments along the line 45. A plasma detector is a “segment detector” if the length (L_{S}) of the detector along the line 45 exceeds a specified threshold fraction (Fₜₕ) of the entire length (L) of the line 45 within the plasma chamber 10. Examples of the threshold fraction Fₜₕ comprise, inter alia, 0.01, 0.05, 0.10, etc. Although the detectors 78-80 are about uniformly distributed along the line 45 in FIG. 7C, the detectors 78-80 may alternatively be non-uniformly distributed along the line 45.

FIG. 7D depicts a plasma detector 81 mounted on the surface 14 and extending continuously across the entire surface 14 along the line 45 and is accordingly called a “maximum segment detector”, since detector 81 is a segment detector having a maximum possible segment length.

FIG. 8A depicts plasma detectors 84, 86, 88, and 89 mounted on the barrier surface 23 of the confinement barrier 34 (see FIGS. 4-5). The detectors 84, 86, 88, and 89 are about uniformly distributed on the barrier surface 23 with respect to azimuthal angle φ, wherein the angle φ is measured with respect to the central point 9 in the plasma space 36.

FIG. 8B depicts FIG. 8A with additional plasma detectors 85 and 87 mounted on the barrier surface 23, resulting in a non-uniform distribution of the detectors 84-89 with respect to an azimuthal angle φ. The higher density of detectors for the spatial distribution of detectors 84-88 with (respect to the angle φ) than the density of detectors for the spatial distribution of detectors 84, 89, and 88 (respect to the angle φ) may reflect such factors as, inter alia: a higher expectation of loss of plasma range of into the space where the detectors 84-88 are located than into the space where the detectors 84, 89, and 88 are located; a lower solid angular range of detection sensitivity for detectors 84-88 than for the detectors 84, 89, and 88, etc.

FIG. 8C depicts plasma detectors 90-92 mounted on the barrier surface 23, resulting in an about uniform distribution of the detectors 90-92 on the barrier surface 23 with respect to an azimuthal angle φ. Alternatively, the detectors 90-92 could be non-uniformly distributed on the barrier surface 23 with respect to the azimuthal angle φ. The detector 90 extends continuously over an azimuthal angular extent φ₁. The detector 91 extends continuously over an azimuthal angular extent φ₂. The detector 92 extends continuously over an azimuthal angular extent φ₃.

FIG. 8D depicts a plasma detector 93 mounted on the barrier surface 23 and extending continuously in a ring formation. Thus similar to detector 69 of FIG. 6D, detector 93 is a ring detector. Note if the angular extents φ₁-φ₃ of detectors 90-92 of FIG. 8C were increased sufficiently to make detectors 90-92 continuous with respect to each other, then the ring detector 93 of FIG. 8D would result.

Distributions of plasma detectors discussed supra with respect to FIGS. 6-8 may be combined in any manner. For illustrative purposes, FIG. 9 depicts an example of such a combination of plasma detectors. In FIG. 9, plasma detectors 94-96 and 97 are mounted on the surface 14 (i.e., on the top wall 11 and/or the bottom wall 12, and plasma detectors 98-99 are mounted on the barrier surface 23 of the confinement barrier 34 (see FIGS. 4-5). In one embodiment, the detectors 94-97 may each be mounted on the surface 21 of the top wall 11. In one embodiment, the detectors 94-97 may each be mounted on the surface 22 of the bottom wall 12. In one embodiment, the detectors 94-96 may each be mounted on the surface 21 of the top wall 11, and the detector 97 may be mounted on the surface 22 of the bottom wall 12. In one embodiment, the detector 97 may be mounted on the surface 21 of the top wall 11, and the detectors 94-96 may each be mounted on the surface 22 of the bottom wall 12.

The preceding embodiments of FIGS. 6-9 are merely illustrative. The scope of the present invention includes any distribution of any number of plasma detectors on any combination of the top wall 11, the bottom wall 12, and the barrier surface 23 (including no detectors on any combination of the bottom wall 11, the top wall 12, and the barrier surface 23), wherein each detector may independently be any type of plasma detector (e.g., Langmuir probe, photodetector, etc.).

Although the confinement barrier 34 is depicted as having a circular shape in the top view of FIGS. 6-9, the confinement barrier 34 may have any other geometrical shape such as, inter alia, an elliptical shape, a rectangular shape, a polygonal shape for a polygon of at least 4 sides (e.g., rectangular, square, pentagonal, hexagonal, etc.), etc.

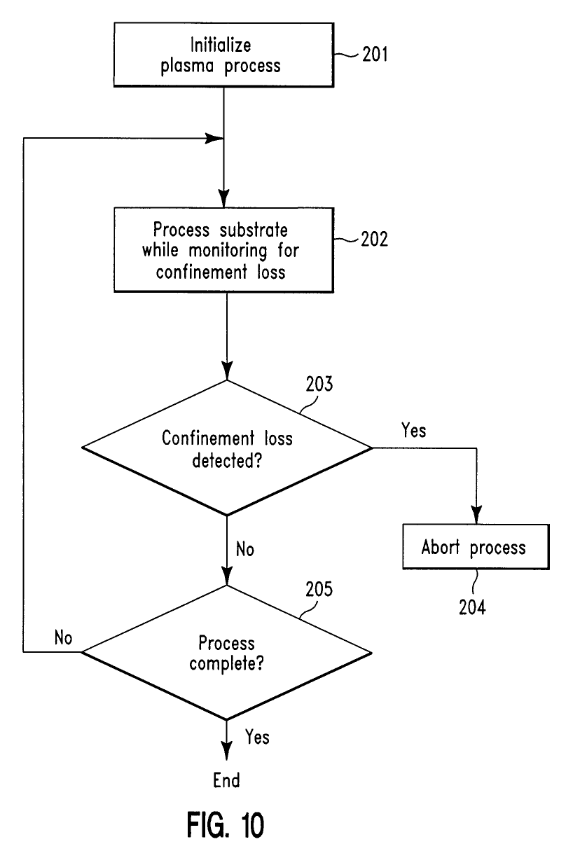

FIG. 10 is a flow chart depicting steps 201-205 of a method for detecting a loss of plasma confinement during operation of a plasma apparatus within the plasma chamber 10 of FIGS. 4-5, in accordance with embodiments of the present invention. Step 201 initializes an operational plasma process performed by the plasma 40 on the substrate 25 that is disposed within the plasma space 36 of the plasma chamber 10. For example, the operational process on the substrate 25 may comprise etching the substrate 25 by the plasma 40. The substrate 25 may be a semiconductor wafer.

Step 202 processes the substrate 25 while plasma detectors in the non-plasma space 38 of the plasma chamber 10 are monitoring for loss of confinement of the plasma 40 in the plasma space 36. The plasma detectors perform the monitoring by being activated to detect escaped plasma disposed in the non-plasma space 38 (e.g., the plasma 145 of FIG. 3).

In step 203, it is determined if loss of plasma confinement has been detected by the plasma detectors in the non-plasma space 38. If it is determined in step 203 that loss of plasma confinement has been detected, then the operational plasma process is aborted in step 204, which prevents damage to the substrate 25 that may occur if the operational plasma process were not aborted.

If it is determined in step 203 that loss of plasma confinement has not been detected, then it is determined in step 205 whether the operational plasma process has been completed. If it is determined in step 205 that the operational plasma process has been completed then the method ends.

If it is determined in step 205 that the operational plasma process has not been completed then the method loops back to step 202 to continue processing the substrate 25 and monitoring for loss of confinement of the plasma 40 in the plasma space 36.

While embodiments of the present invention have been described herein for purposes of illustration, many modifications and changes will become apparent to those skilled in the art. Accordingly, the appended claims are intended to encompass all such modifications and changes as fall within the true spirit and scope of this invention.

What is claimed is:

1. A system for detecting a loss of plasma confinement, comprising:
a plasma chamber enclosed by a first wall, a second wall opposite the first wall, and a sidewall disposed between the first wall and the second wall, said first and second walls having respective first and second surfaces which bound an interior space of the plasma chamber, said interior space of the plasma chamber comprising a plasma space and a non-plasma space, said non-plasma space surrounding and being exterior to the plasma space, said plasma chamber having a plasma apparatus therein for generating a plasma within the plasma space;
a confinement barrier within the plasma chamber and bounding the plasma space, said confinement barrier having a barrier surface exterior to the plasma space and facing the non-plasma space, said confinement barrier adapted to confine the plasma within the plasma space during a performance of an operational process by the plasma on a substrate that is disposed within the plasma space; and N
plasma detectors, said N at least 1, each detector of the N detectors independently mounted on a mounting surface selected from the group consisting of the first surface, the second surface, and the barrier surface, each plasma detector adapted to detect in the non-plasma space escaped plasma that has escaped from the plasma space during the performance of the operational process.

2. The system of claim 1, wherein the N plasma detector comprise N₁ plasma detectors on the first surface and N₂ plasma detectors on the second surface, wherein N₁ is at least 1, and wherein N₂ is at least 1.

3. The system of claim 2, wherein N₁ is at least 2, wherein the N₁ plasma detectors comprise a ring detector, wherein N₂ is at least 2, wherein the N plasma detector further comprise N₃ plasma detectors on the barrier surface, and wherein N₃ is at least 1.

4. The system of claim 2, wherein the N₁ plasma detectors consist of a ring detector.

5. The system of claim 2, wherein N₁ is at least 2, and wherein the N₁ plasma detectors are about uniformly distributed azimuthally on the first surface.

6. The system of claim 2, wherein N₁ is at least 2, and wherein the N₁ plasma detectors are about non-uniformly distributed azimuthally on the first surface.

7. The system of claim 2, wherein N₁ is at least 2, wherein a solid angular range of detection of a first plasma detector of the N₁ detectors exceeds a solid angular range of detection of a second plasma detector of the N₁ detectors.

8. The system of claim 2, wherein the N plasma detector further comprise N₃ plasma detectors on the barrier surface, and wherein N₃ is at least 1.

9. The method of claim 2, wherein the N₁ plasma detectors and the N₂ plasma detectors collectively comprise at least one Langmuir probe and at least one photodetector.

10. The system of claim 1, wherein the operational process on the substrate comprises an etching of the substrate, and wherein the substrate is a semiconductor wafer.

11. A method for detecting a loss of plasma confinement, comprising:
providing a system, said system comprising:
a plasma chamber enclosed by a first wall, a second wall opposite the first wall, and a sidewall disposed between the first wall and the second wall, said first and second walls having respective first and second surfaces which bound an interior space of the plasma chamber, said interior space of the plasma chamber comprising a plasma space and a non-plasma space, said non-plasma space surrounding and being exterior to the plasma space, said plasma chamber having a plasma apparatus therein for generating a plasma within the plasma space;
a confinement barrier within the plasma chamber and bounding the plasma space, said confinement barrier having a barrier surface exterior to the plasma space and facing the non-plasma space, said confinement barrier adapted to confine the plasma within the plasma space during a performance of an operational process by the plasma on a substrate that is disposed within the plasma space; and
N plasma detectors, said N at least 1, each detector of the N detectors independently mounted on a mounting surface selected from the group consisting of the first surface, the second surface, and the barrier surface, each plasma detector adapted to detect in the non-plasma space escaped plasma that has escaped from the plasma space during the performance of the operational process;
initiating the operational process by the plasma on the substrate;
performing the operational process while monitoring the non-plasma space for a presence of said escaped plasma in the non-plasma space, said monitoring being conducted by the at least one plasma detector; and
if said monitoring has detected said escaped plasma, then aborting the operational process, else continuing said performing the operational process until either the operational process has been completed or said monitoring has detected said escaped plasma.

12. The method of claim 11, wherein the N plasma detector comprise N₁ plasma detectors on the first surface and N₂ plasma detectors on the second surface, wherein N₁ is at least 1, and wherein N₂ is at least 1.

13. The method of claim 12, wherein the N₁ plasma detectors and the N₂ plasma detectors collectively comprise a plurality of Langmuir probes.

14. The method of claim 12, wherein the N₁ plasma detectors and the N₂ plasma detectors collectively comprise a plurality of photodetectors.

15. The method of claim 12, wherein the N₁ plasma detectors and the N₂ plasma detectors collectively comprise at least one Langmuir probe and at least one photodetector.

16. The method of claim 12, wherein the N plasma detector further comprise N₃ plasma detectors on the barrier surface, and wherein N₃ is at least 1.

17. The method of claim 16, wherein N₃ is at least 2, and wherein the N₃ plasma detectors are about uniformly distributed azimuthally on the barrier surface.

18. The method of claim 16, wherein N₃ is at least 2, and wherein the N₃ plasma detectors are non-uniformly distributed azimuthally on the barrier surface.

19. The system of claim 12, wherein N₁ is at least 2, wherein a solid angular range of detection of a first plasma detector of the N₁ detectors exceeds a solid angular range of detection of a second plasma detector of the N₁ detectors.

20. The method of claim 11, wherein the operational process on the substrate comprises an etching of the substrate, and wherein the substrate is a semiconductor wafer.
